(19) United States
(12) Patent Application Publication
(10) Pub. No.: US 2025/0284858 A1
(43) Pub. Date: Sep. 11, 2025

(54) Actors with Selective Intelligence in Simulation

(71) Applicant: Aurora Operations, Inc., Pittsburgh, PA (US)

(72) Inventors: Juan Pablo Mendoza, San Francisco, CA (US); Ranjith Unnikrishnan, Fremont, CA (US); Samarth Wahal, Pittsburgh, PA (US); Lingyao Zhang, Mountain View, CA (US)

(21) Appl. No.: 18/495,577

(22) Filed: Oct. 26, 2023

(51) Int. Cl. G06F 30/20; B60W 60/00; G06F 11/34

(52) U.S. Cl. CPC G06F 30/20; B60W 60/00274; G06F 11/3409

(57) ABSTRACT

Evaluating the performance of an autonomous vehicle includes determining a simulation scenario from log data, the simulation scenario including a non-AV actor enabled to selectively deviate from its logged trajectory during simulation, executing the simulation based on the simulation scenario, monitoring the execution of the simulation, determining whether a behavior-switching condition for the non-AV actor in association with a traffic interaction including the AV is satisfied during the simulation based on the monitoring, modifying, using a first behavioral model, a behavior of the non-AV actor to deviate from its logged trajectory responsive to determining that the behavior-switching condition for the non-AV actor in association with the traffic interaction including the AV is satisfied during the simulation, and determining a performance metric based on the simulation.

### BACKGROUND

A challenge to autonomous vehicle technology arises in evaluating the performance of different subsystems of the autonomous vehicle under a wide variety of driving circumstances in the real world. Practically, the different subsystems of the autonomous vehicle may be evaluated on a plurality of log-based simulation scenarios that attempt to mimic the real world. For example, the perception or planning subsystems in an autonomous vehicle may be evaluated on simulated scenarios to determine whether the autonomous vehicle is navigating appropriately through the environment. There exists a persistent need for a technique to evaluate the performance of the autonomous vehicle in simulated scenarios where actors are enabled to selectively adapt to new environmental changes that occur during simulation.

### SUMMARY

The present disclosure describes techniques for evaluating the performance of an autonomous vehicle in simulation scenarios using intelligent actors. For example, the intelligent actors may be actors that are enabled to selectively adapt their responsiveness to new environmental changes that occur during simulation. One existing approach for evaluating the performance of the autonomous vehicle is to test its behavior in the simulation scenarios using scripted actors. A scripted actor follows the original trajectory (logged trajectory) observed in the log file collected from real-world driving. Although the scripted actor may possess good accuracy in terms of replaying a trajectory from the original log, it may have bad responsiveness in terms of adapting to the planned behavior exhibited by the autonomous vehicle in the simulation. For example, the scripted actor can rear-end the autonomous vehicle or conduct a lane change even though the autonomous vehicle is already present or going to be present in the conflicted lane. As such, the existing approach reduces the signal-to-noise ratio for metrics measured from the simulations and may not facilitate accurately evaluating the performance of the autonomous vehicle. For example, the metrics may measure instances of suboptimal outcomes in the performance of the autonomous vehicle. The present disclosure is particularly advantageous for evaluating the performance of the autonomous vehicle because the intelligent actors may be equipped to selectively deviate from the logged trajectory in response to new environmental changes, such as the planned trajectory of the autonomous vehicle in the simulation. The present disclosure is additionally advantageous because the actor model parameters used in the intelligent actors are optimized to maintain a minimum scene divergence from the logged trajectory in the simulations once the selective deviation from the logged trajectory is initiated.

This specification relates to methods and systems for evaluating the performance of an autonomous vehicle in the simulation scenarios using intelligent actors. According to one aspect of the subject matter described in this disclosure, a method includes determining a simulation scenario from log data, the simulation scenario including a first non-AV actor enabled to selectively deviate from its logged trajectory in the log data during simulation, executing the simulation based on the simulation scenario, monitoring the execution of the simulation, determining whether a behavior-switching condition for the first non-AV actor in association with a traffic interaction including the AV is satisfied during the simulation based on the monitoring, modifying, using a first behavioral model, a behavior of the first non-AV actor to deviate from its logged trajectory responsive to determining that the behavior-switching condition for the first non-AV actor in association with the traffic interaction including the AV is satisfied during the simulation, and determining a performance metric based on the simulation.

In general, another aspect of the subject matter described in this disclosure includes a system comprising one or more processors and memory operably coupled with the one or more processors, wherein the memory stores instructions that, in response to the execution of the instructions by one or more processors, cause the one or more processors to perform operations including determining a simulation scenario from log data, the simulation scenario including a first non-AV actor enabled to selectively deviate from its logged trajectory in the log data during simulation, executing the simulation based on the simulation scenario, monitoring the execution of the simulation, determining whether a behavior-switching condition for the first non-AV actor in association with a traffic interaction including the AV is satisfied during the simulation based on the monitoring, modifying, using a first behavioral model, a behavior of the first non-AV actor to deviate from its logged trajectory responsive to determining that the behavior-switching condition for the first non-AV actor in association with the traffic interaction including the AV is satisfied during the simulation, and determining a performance metric based on the simulation.

Other implementations of one or more of these aspects include corresponding systems, apparatus, and computer programs, configured to perform the actions of the methods, encoded on computer storage devices.

These and other implementations may each optionally include one or more of the following aspects. For instance, the aspects may also include determining whether a behavior-switching condition for a second non-AV actor in association with the first non-AV actor is satisfied during the simulation responsive to modifying the behavior of the first non-AV actor to deviate from its logged trajectory, the second non-AV actor included in the simulation scenario and enabled to selectively deviate from its logged trajectory in the log data during the simulation, and modifying, using a second behavior model, a behavior of the second non-AV actor to deviate from its logged trajectory responsive to determining that the behavior-switching condition for the second non-AV actor in association with the first non-AV actor is satisfied during the simulation. For instance, the aspects may also include that determining whether the behavior-switching condition for the first non-AV actor in association with the traffic interaction including the AV is satisfied during the simulation includes determining a future logged trajectory of the first non-AV actor in the simulation, determining a future trajectory of the AV in the simulation, and determining whether the first non-AV actor has a traffic conflict with the AV at a future point in time and space in the simulation using the future logged trajectory of the first non-AV actor and the future trajectory of the AV. In another example, the aspects may also include that the traffic conflict defines the behavior-switching condition. For instance, the aspects may also include that determining whether the first non-AV actor has the traffic conflict with the AV at the future point in time and space in the simulation using the future logged trajectory of the first non-AV actor and the future trajectory of the AV includes projecting the future trajectory of the AV onto a frame of reference of the first non-AV actor, and determining, at each of a plurality of discrete time steps along the projected future trajectory of the AV, whether the first non-AV actor has the traffic conflict with the AV. For instance, the aspects may also include that modifying the behavior of the first non-AV actor to deviate from its logged trajectory includes modifying an acceleration of the first non-AV actor. For instance, the aspects may further include that modifying the acceleration of the first non-AV actor includes determining the acceleration of the first non-AV actor that maintains an acceptable following distance behind the AV in a same lane as the AV, determining the acceleration of the first non-AV actor that prevents a collision with the AV, determining whether the first non-AV actor has to yield to the AV in a traffic conflict, the traffic conflict being a merge and determining the acceleration of the first non-AV actor to yield to the AV responsive to determining that the first non-AV actor has to yield to the AV in the traffic conflict, determining whether the first non-AV actor has a right of way in the traffic conflict with the AV, the traffic conflict being an intersection, and determining the acceleration of the first non-AV actor to stop at the intersection responsive to determining that the first non-AV actor has no right of way in the traffic conflict with the AV. For instance, the aspects may also include the behavior switching condition evaluating at least one from a group of: a deviation of the AV from its logged trajectory in the log data during the traffic interaction with the non-AV actor, a divergence threshold between a planned trajectory of the AV and its logged trajectory in the log data, a current distance threshold between the AV and the first non-AV actor, a change in a state of dynamic elements other than non-AV actors, a presence of static elements, and a proximity to traffic infrastructure. For instance, the aspects may further include that determining the performance metric based on the simulation includes determining an evaluation set of simulation scenarios, each simulation scenario in the evaluation set including one or more non-AV actors enabled to selectively deviate from their logged trajectory, executing the simulation for each simulation scenario in the evaluation set, and determining a precision and recall of the performance metric based on the simulation. In another example, the aspects may also include that the performance metric measures instances of a suboptimal outcome in the performance of the AV. In another example, the aspects may further include that the first and the second behavior models are machine learning models, each trained from a plurality of logged trajectories of actors in real-world driving data. In another example, the aspects may also include that parameters of the first and the second behavior models are optimized using a nonlinear least squares optimization method to follow logged trajectories.

### BRIEF DESCRIPTION OF THE DRAWINGS

These and other aspects and features of the present implementations will become apparent upon review of the following description of specific implementations in conjunction with the accompanying figures, wherein:

FIG. 1 is a block diagram illustrating an example hardware and software environment for an autonomous vehicle according to some implementations.

FIG. 2 is a block diagram illustrating an example computing system for evaluating the performance of an autonomous vehicle in the simulation scenarios using intelligent actors according to some implementations.

FIG. 3A is a block diagram illustrating an example implementation of a simulation management engine referenced in FIG. 2.

FIG. 3B is a block diagram illustrating an example implementation of a simulation execution engine referenced in FIG. 2.

FIG. 3C is a block diagram illustrating an example implementation of a simulation validation engine referenced in FIG. 2

FIG. 4 is a flow chart illustrating a method of evaluating a performance of an autonomous vehicle according to some implementations.

FIG. 5 is a flow chart illustrating a method of modifying a behavior of a non-AV actor according to some implementations.

### DETAILED DESCRIPTION

### Overview

In the following disclosure, an intelligent simulation from log (SFL) system 160 is used to evaluate the performance of an autonomous vehicle (AV) in a set of simulation scenarios using intelligent actors. In some implementations, the intelligent actors may be used as a replacement of the existing scripted actors in simulation scenarios. An intelligent actor may be defined as an integrated actor or a reactive actor that is enabled to selectively deviate from a logged trajectory during a simulation run based on the simulation scenario. For example, the intelligent actor may be non-AV actor, such as an intelligent path follower (IPF) actor with a set of capabilities to selectively deviate from a logged trajectory, such as merge interaction reasoning, adaptive cruise control (ACC), intersection navigation handling, collision avoidance, etc. enabled during the creation of the simulation scenario. A simulation scenario may describe a three-dimensional scene (e.g., a virtual scene) that simulates the behavior, properties, and sensor configuration of the AV in a specific encounter with the environment including other vehicle actors (autonomous and/or non-autonomous) at rest or in motion, pedestrian actors, wildlife actors, time of day, weather conditions, terrain, and road surface markings, among other things. For example, the simulation scenarios may include perception scenarios, perception simulation scenarios, motion planning simulations scenarios, vehicle detection and tracking (VDT) scenarios, etc.

The intelligent SFL system 160 evaluates the performance of the AV in a simulation scenario using one or more intelligent non-AV actors. The intelligent actors may be enabled to selectively deviate from the logged trajectory in response to new environmental changes, such as the planned trajectory of the AV during the simulation. For example, the intelligent actor may choose to selectively deviate from the logged trajectory in response to the planned trajectory of the AV (that is also intelligent as described herein) in the simulation satisfying a behavior-switching condition for the intelligent actor. The intelligent SFL system 160 uses a behavior model to modify the behavior of the intelligent actor to deviate from the logged trajectory. An existing approach for evaluating the performance of the AV is to use scripted actors in the simulation scenarios. A scripted actor follows the original trajectory (logged trajectory) observed in the log file collected from real-world driving. In other words, the scripted actor is configured to follow a predefined temporal trajectory in the simulation. However, the scripted actors faithfully replaying the logged trajectory in the simulation when the AV is executing on a planned trajectory that diverges from the original log, such as making a courtesy lane change, accelerating or decelerating along a current lane, etc. leads to an observation of some unreasonable actor behaviors from the scripted actors that a reasonable driver would not exhibit in a real-world driving scenario. Such unreasonable actor behaviors make the simulations used to evaluate the performance of the autonomous vehicle invalid for the wrong reasons.

The present disclosure is particularly advantageous because it provides a system and method for evaluating the performance of the AV in simulation scenarios by using intelligent non-AV actors (i.e., intelligent simulation scenarios) that are equipped to selectively deviate from the logged trajectory. For example, the “intelligence” of the intelligent actor to selectively deviate from the logged trajectory may allow the intelligent actor to avoid an unrealistic behavior in a traffic interaction with the AV in the simulation that a human driver would not exhibit in the real world. This improves the precision of the metric that measures instances of a suboptimal outcome (e.g., collision) in the AV's performance as determined from the simulations of intelligent simulation scenarios while maintaining the recall of the metric. Furthermore, the actor model parameters for the intelligent actors used in the simulation scenarios are optimized to maintain a minimum scene divergence from the logged trajectory in the simulations once the selective deviation from the logged trajectory is initiated. By enabling the non-AV actors in the simulation scenarios to avoid unrealistic behaviors in traffic interactions with the AV while maintaining a minimum scene divergence from the logged trajectory, the present disclosure reduces false positive instances of suboptimal outcomes (i.e. where the AV's performance or behavior is incorrectly considered at fault for the suboptimal outcome) and improves the log trajectory reproducibility of the intelligent actors (i.e. preserving the actor behavior from the original log for minimal scene divergence) in the simulations. Thus, the present disclosure improves the effectiveness of evaluating and validating the performance of the AV in the simulation scenarios. Furthermore, the present disclosure improves the accuracy and the utility of the simulation scenarios in conducting effective autonomous vehicle testing.

### Autonomous Vehicle

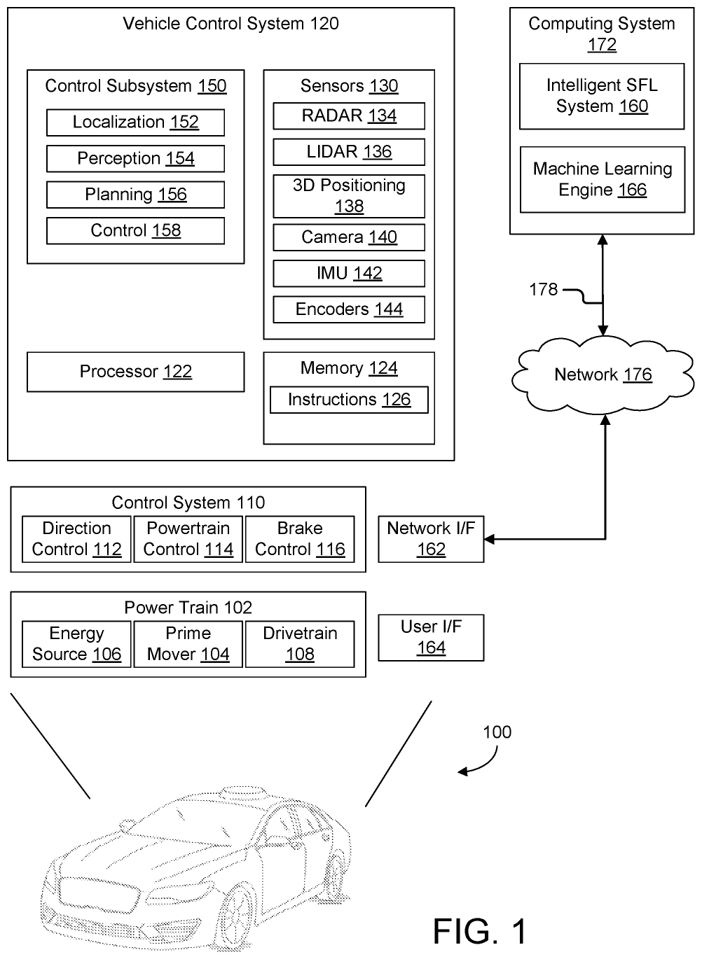

Referring to the drawings, wherein like numbers denote like parts throughout the several views, FIG. 1 illustrates an example hardware and software environment for an autonomous vehicle within which various techniques disclosed herein may be implemented. The vehicle 100, for example, may include a powertrain 102 including a prime mover 104 powered by an energy source 106 and capable of providing power to a drivetrain 108, as well as a control system 110 including a direction control 112, a powertrain control 114, and a brake control 116. The vehicle 100 may be implemented as any number of different types of vehicles, including vehicles capable of transporting people and/or cargo, and capable of traveling by land, by sea, by air, underground, undersea, and/or in space, and it will be appreciated that the aforementioned components 102-116 may vary widely based upon the type of vehicle within which these components are utilized.

For simplicity, the implementations discussed hereinafter will focus on a wheeled land vehicle such as a car, van, truck, bus, etc. In such implementations, the prime mover 104 may include one or more electric motors and/or an internal combustion engine (among others). The energy source 106 may include, for example, a fuel system (e.g., providing gasoline, diesel, hydrogen, etc.), a battery system, solar panels or other renewable energy source, and/or a fuel cell system. The drivetrain 108 includes wheels and/or tires along with a transmission and/or any other mechanical drive components suitable for converting the output of the prime mover 104 into vehicular motion, as well as one or more brakes configured to controllably stop or slow the vehicle 100 and direction or steering components suitable for controlling the trajectory of the vehicle 100 (e.g., a rack and pinion steering linkage enabling one or more wheels of the vehicle 100 to pivot about a generally vertical axis to vary an angle of the rotational planes of the wheels relative to the longitudinal axis of the vehicle). In some implementations, combinations of powertrains and energy sources may be used (e.g., in the case of electric/gas hybrid vehicles), and in some implementations, multiple electric motors (e.g., dedicated to individual wheels or axles) may be used as a prime mover. In the case of a hydrogen fuel cell implementation, the prime mover 104 may include one or more electric motors and the energy source 106 may include a fuel cell system powered by hydrogen fuel.

The direction control 112 may include one or more actuators and/or sensors for controlling and receiving feedback from the direction or steering components to enable the vehicle 100 to follow a desired trajectory. The powertrain control 114 may be configured to control the output of the powertrain 102, e.g., to control the output power of the prime mover 104, to control a gear of a transmission in the drivetrain 108, etc., thereby controlling a speed and/or direction of the vehicle 100. The brake control 116 may be configured to control one or more brakes that slow or stop vehicle 100, e.g., disk or drum brakes coupled to the wheels of the vehicle.

Other vehicle types, including but not limited to airplanes, space vehicles, helicopters, drones, military vehicles, all-terrain or tracked vehicles, ships, submarines, construction equipment etc., will necessarily utilize different powertrains, drivetrains, energy sources, direction controls, powertrain controls and brake controls. Moreover, in some implementations, some of the components can be combined, e.g., where directional control of a vehicle is primarily handled by varying an output of one or more prime movers. Therefore, implementations disclosed herein are not limited to the particular application of the herein-described techniques in an autonomous wheeled land vehicle.

In the illustrated implementation, full or semi-autonomous control over the vehicle 100 is implemented in a vehicle control system 120, which may include one or more processors 122 and one or more memories 124, with each processor 122 configured to execute program code instructions 126 stored in a memory 124. The processors(s) can include, for example, graphics processing unit(s) (“GPU(s)”)) and/or central processing unit(s) (“CPU(s)”).

Sensors 130 may include various sensors suitable for collecting information from a vehicle's surrounding environment for use in controlling the operation of the vehicle 100. For example, sensors 130 can include RADAR sensor 134, LIDAR (Light Detection and Ranging) sensor 136, a 3D positioning sensor 138, e.g., a satellite navigation system such as GPS (Global Positioning System), GLONASS (Globalnaya Navigazionnaya Sputnikovaya Sistema, or Global Navigation Satellite System), BeiDou Navigation Satellite System (BDS), Galileo, Compass, etc. The 3D positioning sensors 138 can be used to determine the location of the vehicle on the Earth using satellite signals. The sensors 130 can optionally include a camera 140 and/or an IMU (inertial measurement unit) 142. The camera 140 can be a monographic or stereographic camera and can record still and/or video images. The IMU 142 can include multiple gyroscopes and accelerometers capable of detecting linear and rotational motion of the vehicle 100 in three directions. One or more encoders 144, such as wheel encoders may be used to monitor the rotation of one or more wheels of vehicle 100.

The outputs of sensors 130 may be provided to a set of control subsystems 150, including, a localization subsystem 152, a perception subsystem 154, a planning subsystem 156, and a control subsystem 158. The localization subsystem 152 is principally responsible for precisely determining the location and orientation (also sometimes referred to as “pose”) of the vehicle 100 within its surrounding environment, and generally within some frame of reference. The perception subsystem 154 is principally responsible for detecting, tracking, and/or identifying objects within the environment surrounding vehicle 100. A machine learning model in accordance with some implementations can be utilized in tracking objects. The planning subsystem 156 is principally responsible for planning a trajectory or a path of motion for vehicle 100 over some timeframe given a desired destination as well as the static and moving objects within the environment. A machine learning model in accordance with some implementations can be utilized in planning a vehicle trajectory. The control subsystem 158 is principally responsible for generating suitable control signals for controlling the various controls in the vehicle control system 120 in order to implement the planned trajectory of the vehicle 100. Similarly, a machine learning model can be utilized to generate one or more signals to control the autonomous vehicle 100 to implement the planned trajectory.

It will be appreciated that the collection of components illustrated in FIG. 1 for the vehicle control system 120 is merely one example. Individual sensors may be omitted in some implementations. Additionally, or alternatively, in some implementations, multiple sensors of the same types illustrated in FIG. 1 may be used for redundancy and/or to cover different regions around a vehicle. Moreover, there may be additional sensors beyond those described above to provide actual sensor data related to the operation and environment of the wheeled land vehicle. Likewise, different types and/or combinations of control subsystems may be used in other implementations. Further, while subsystems 152-160 are illustrated as being separate from processor 122 and memory 124, it will be appreciated that in some implementations, some or all of the functionality of a subsystem 152-160 may be implemented with program code instructions 126 resident in one or more memories 124 and executed by one or more processors 122, and that these subsystems 152-160 may in some instances be implemented using the same processor(s) and/or memory. Subsystems may be implemented at least in part using various dedicated circuit logic, various processors, various field programmable gate arrays (“FPGA”), various application-specific integrated circuits (“ASIC”), various real time controllers, and the like, as noted above, multiple subsystems may utilize circuitry, processors, sensors, and/or other components. Further, the various components in the vehicle control system 120 may be networked in various manners.

In some implementations, the vehicle 100 may also include a secondary vehicle control system (not illustrated), which may be used as a redundant or backup control system for the vehicle 100. In some implementations, the secondary vehicle control system may be capable of fully operating the autonomous vehicle 100 in the event of an adverse event in the vehicle control system 120, while in other implementations, the secondary vehicle control system may only have limited functionality, e.g., to perform a controlled stop of the vehicle 100 in response to an adverse event detected in the primary vehicle control system 120. In still other implementations, the secondary vehicle control system may be omitted.

In general, an innumerable number of different architectures, including various combinations of software, hardware, circuit logic, sensors, networks, etc. may be used to implement the various components illustrated in FIG. 1. Each processor may be implemented, for example, as a microprocessor and each memory may represent the random access memory (“RAM”) devices comprising a main storage, as well as any supplemental levels of memory, e.g., cache memories, non-volatile or backup memories (e.g., programmable or flash memories), read-only memories, etc. In addition, each memory may be considered to include memory storage physically located elsewhere in the vehicle 100, e.g., any cache memory in a processor, as well as any storage capacity used as a virtual memory, e.g., as stored on a mass storage device or another computer controller. One or more processors 122 illustrated in FIG. 1, or entirely separate processors, may be used to implement additional functionality in the vehicle 100 outside of the purposes of autonomous control, e.g., to control entertainment systems, to operate doors, lights, convenience features, etc.

In addition, for additional storage, the vehicle 100 may include one or more mass storage devices, e.g., a removable disk drive, a hard disk drive, a direct access storage device (“DASD”), an optical drive (e.g., a CD drive, a DVD drive, etc.), a solid state storage drive (“SSD”), network attached storage, a storage area network, and/or a tape drive, among others.

Furthermore, the vehicle 100 may include a user interface 164 to enable vehicle 100 to receive a number of inputs from and generate outputs for a user or operator, e.g., one or more displays, touchscreens, voice and/or gesture interfaces, buttons and other tactile controls, etc. Otherwise, user input may be received via another computer or electronic device, e.g., via an app on a mobile device or via a web interface.

Moreover, the vehicle 100 may include one or more network interfaces, e.g., network interface 162, suitable for communicating with one or more networks 176 to permit the communication of information with other computers and electronic devices, including, for example, a central service, such as a cloud service, from which the vehicle 100 receives information including trained machine learning models and other data for use in autonomous control thereof. The one or more networks 176, for example, may be a communication network that includes a wide area network (“WAN”) such as the Internet, one or more local area networks (“LANs”) such as Wi-Fi LANs, mesh networks, etc., and one or more bus subsystems. The one or more networks 176 may optionally utilize one or more standard communication technologies, protocols, and/or inter-process communication techniques. In some implementations, data collected by the one or more sensors 130 can be uploaded to a computing system 172 via the network 176 for additional processing.

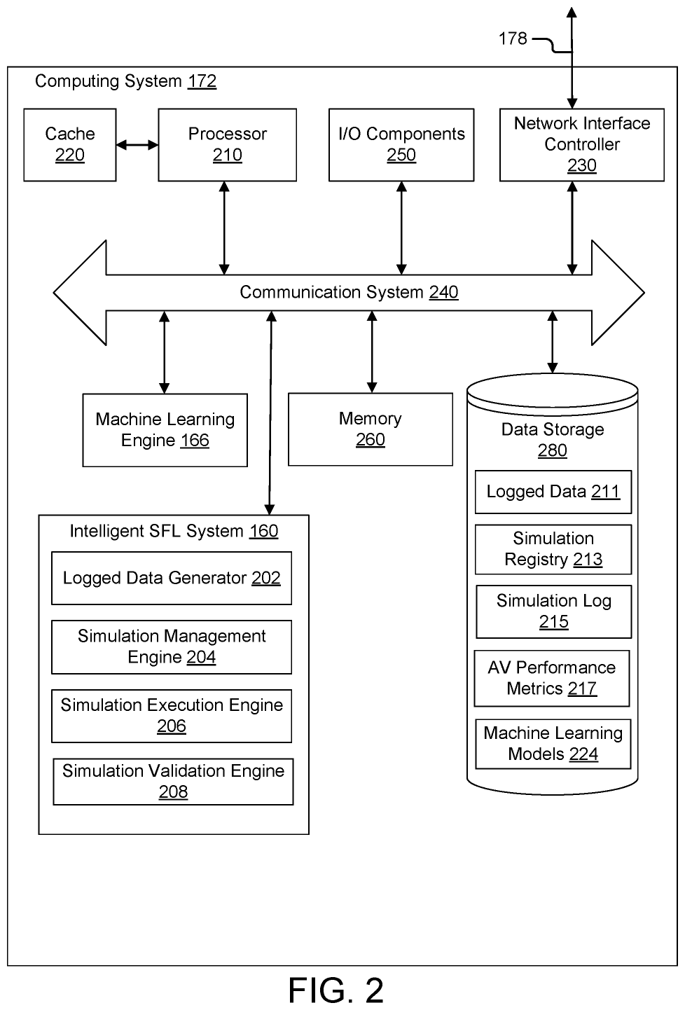

In the illustrated implementation, the vehicle 100 may communicate via the network 176 with a computing system 172 for the purposes of implementing various functions described below for evaluating the performance of an autonomous vehicle in the simulation scenarios using intelligent actors. In some implementations, computing system 172 is a cloud-based computing device. As described below in more detail with reference to FIG. 2, the computing system 172 includes an intelligent simulation from log (SFL) system 160 and a machine learning engine 166. For example, in some implementations, the intelligent SFL system 160 operates on the computing system 172 to determine a simulation scenario including a non-AV actor, execute a simulation of a simulation scenario, monitor the execution of the simulation, determine whether a behavior-switching condition for the non-AV actor in association with the AV is satisfied, modify a behavior of the non-AV actor to deviate from its logged trajectory using a behavior model trained by the machine learning engine 166 if the behavior-switching condition is satisfied, and determine a collision metric in association with the AV based on the simulation.

Each processor illustrated in FIG. 1, as well as various additional controllers and subsystems disclosed herein, generally operates under the control of an operating system and executes or otherwise relies upon various computer software applications, components, programs, objects, modules, data structures, etc., as will be described in greater detail below. Moreover, various applications, components, programs, objects, modules, etc. may also execute on one or more processors in another computer (e.g., computing system 172) coupled to vehicle 100 via network 176, e.g., in a distributed, cloud-based, or client-server computing environment, whereby the processing required to implement the functions of a computer program may be allocated to multiple computers and/or services over a network.

In general, the routines executed to implement the various implementations described herein, whether implemented as part of an operating system or a specific application, component, program, object, module or sequence of instructions, or even a subset thereof, will be referred to herein as “program code.” Program code typically comprises one or more instructions that are resident at various times in various memory and storage devices, and that, when read and executed by one or more processors, perform the steps necessary to execute steps or elements embodying the various aspects of the present disclosure. Moreover, while implementations have and hereinafter will be described in the context of fully functioning computers and systems, it will be appreciated that the various implementations described herein are capable of being distributed as a program product in a variety of forms, and that implementations can be implemented regardless of the particular type of computer readable media used to actually carry out the distribution.

Examples of computer readable media include tangible, non-transitory media such as volatile and non-volatile memory devices, floppy and other removable disks, solid state drives, hard disk drives, magnetic tape, and optical disks (e.g., CD-ROMs, DVDs, etc.) among others.

In addition, various program codes described hereinafter may be identified based upon the application within which it is implemented in a specific implementation. However, it should be appreciated that any particular program nomenclature that follows is used merely for convenience, and thus the present disclosure should not be limited to use solely in any specific application identified and/or implied by such nomenclature. Furthermore, given the typically endless number of manners in which computer programs may be organized into routines, procedures, methods, modules, objects, and the like, as well as the various manners in which program functionality may be allocated among various software layers that are resident within a typical computer (e.g., operating systems, libraries, API's, applications, applets, etc.), it should be appreciated that the present disclosure is not limited to the specific organization and allocation of program functionality described herein.

The example environment illustrated in FIG. 1 is not intended to limit implementations disclosed herein. Indeed, other alternative hardware and/or software environments may be used without departing from the scope of implementations disclosed herein.

Intelligent Simulation from Log (SFL) System

FIG. 2 is a block diagram illustrating an example of a computing system 172 for evaluating the performance of an autonomous vehicle in simulation scenarios using intelligent actors, according to some implementations.

Referring to FIG. 2, the illustrated example computing system 172 includes one or more processors 210 in communication, via a communication system 240 (e.g., bus), with memory 260, at least one network interface controller 230 with network interface port for connection to a network (e.g., network 176 via signal line 178), a data storage 280, and other components, e.g., an input/output (“I/O”) components interface 250 connecting to a display (not illustrated) and an input device (not illustrated), an intelligent SFL system 160, and a machine learning engine 166. Generally, the processor(s) 210 will execute instructions (or computer programs) received from memory 260. The processor(s) 210 illustrated incorporate, or are directly connected to, cache memory 220. In some instances, instructions are read from memory 260 into the cache memory 220 and executed by the processor(s) 210 from the cache memory 220.

In more detail, the processor(s) 210 may be any logic circuitry that processes instructions, e.g., instructions fetched from the memory 260 or cache 220. In some implementations, the processor(s) 210 are microprocessor units or special purpose processors. The computing system or device 172 may be based on any processor, or set of processors, capable of operating as described herein. The processor(s) 210 may be a single core or multi-core processor(s). The processor(s) 210 may be multiple distinct processors.

The memory 260 may be any device suitable for storing computer readable data. The memory 260 may be a device with fixed storage or a device for reading removable storage media. Examples include all forms of non-volatile memory, media and memory devices, semiconductor memory devices (e.g., EPROM, EEPROM, SDRAM, and flash memory devices), magnetic disks, magneto optical disks, and optical discs (e.g., CD ROM, DVD-ROM, or Blu-Ray® discs). A computing system 172 may have any number of memory devices as the memory 260. While the intelligent SFL system 160 and the machine learning engine 166 are illustrated as being separate from processor 210 and memory 260, it will be appreciated that in some implementations, some or all of the functionality of the components 160 and 166 may be implemented with program code instructions resident in the memory 260 and executed by the processor 210.

The cache memory 220 is generally a form of computer memory placed in close proximity to the processor(s) 210 for fast read times. In some implementations, the cache memory 220 is part of, or on the same chip as, the processor(s) 210. In some implementations, there are multiple levels of cache 220, e.g., L2 and L3 cache layers.

The network interface controller 230 manages data exchanges via the network interface (sometimes referred to as network interface ports). The network interface controller 230 handles the physical and data link layers of the OSI model for network communication. In some implementations, some of the network interface controller's tasks are handled by one or more of the processors 210. In some implementations, the network interface controller 230 is part of a processor 210. In some implementations, a computing system 172 has multiple network interfaces controlled by a single controller 230. In some implementations, a computing system 172 has multiple network interface controllers 230. In some implementations, each network interface is a connection point for a physical network link (e.g., a cat-5 Ethernet link). In some implementations, the network interface controller 230 supports wireless network connections and an interface port is a wireless (e.g., radio) receiver/transmitter (e.g., for any of the IEEE 802.11 protocols, near field communication “NFC”, Bluetooth, ANT, WiMAX, 5G, or any other wireless protocol). In some implementations, the network interface controller 230 implements one or more network protocols such as Ethernet. Generally, a computing system 172 exchanges data with other computing devices via physical or wireless links (represented by signal line 178) through a network interface. The network interface may link directly to another device or to another device via an intermediary device, e.g., a network device such as a hub, a bridge, a switch, or a router, connecting the computing system 172 to a data network such as the Internet.

The data storage 280 may be a non-transitory storage device that stores data for providing the functionality described herein. The data storage 280 may store, among other data, logged data 211, a simulation registry 213, a simulation log 215, AV performance metrics 217, and machine learning models 224, as will be defined below.

The computing system 172 may include, or provide interfaces for, one or more input or output (“I/O”) devices 250. Input devices include, without limitation, keyboards, microphones, touch screens, foot pedals, sensors, MIDI devices, and pointing devices such as a mouse or trackball. Output devices include, without limitation, video displays, speakers, refreshable Braille terminal, lights, MIDI devices, and 2-D or 3-D printers. Other components may include an I/O interface, external serial device ports, and any additional co-processors. For example, a computing system 172 may include an interface (e.g., a universal serial bus (USB) interface) for connecting input devices, output devices, or additional memory devices (e.g., portable flash drive or external media drive). In some implementations, a computing system 172 includes an additional device such as a co-processor, e.g., a math co-processor can assist the processor 210 with high precision or complex calculations.

In implementations consistent with the disclosure, the intelligent SFL system 160 is utilized to evaluate the performance of an autonomous vehicle (AV) in simulation scenarios using intelligent actors. More specifically, the present disclosure is directed to evaluating the performance of the AV using simulation scenarios in which the intelligent actors may be used as a replacement for scripted actors. An intelligent actor may be defined as an integrated actor or a reactive actor that is enabled to selectively deviate from a logged trajectory during a simulation run based on the simulation scenario. For example, the intelligent actor may be a non-AV actor, such as an intelligent path follower (IPF) actor with a set of capabilities to selectively deviate from a logged trajectory. The set of capabilities may include merge interaction reasoning, adaptive cruise control (ACC), intersection navigation handling, collision avoidance, etc. enabled during the creation of the simulation scenario.

In some implementations, the intelligent SFL system 160 includes a logged data generator 202, a simulation management engine 204, a simulation execution engine 206, and a simulation validation engine 208. The logged data generator 202, the simulation management engine 204, the simulation execution engine 206, and the simulation validation engine 208 of the intelligent SFL system 160 and separately the machine learning engine 166 are example components in which the techniques described herein may be implemented and/or with which systems, components, and techniques described herein may interface. While described in the context of the computing system 172, it should be understood that the operations performed by the one or more components 202, 204, 206, 208, and 166 of FIG. 2 may be distributed across multiple computing systems. In some implementations, one or more aspects of components 202, 204, 206, 208, and 166 may be combined into a single system and/or one or more aspects may be implemented by the computing system 172. For example, in some implementations, aspects of the logged data generator 202 may be combined with aspects of the simulation management engine 204. In another example, aspects of simulation validation engine 208 may be combined with aspects of the simulation execution engine 206. Engines in accordance with many implementations may each be implemented in one or more computing devices that communicate, for example, through the communication network 176.

The logged data generator 202 may receive and store vehicle logged data 211 collected during one or more driving sessions of an autonomous, partially autonomous, or non-autonomous vehicle in the real world. For example, the one or more sensors 130 of the autonomous vehicle (AV) 100 may collect a set of vehicle logged data 211 along one or more driving routes in the real world and upload the collected data to the computing system 172 via the network 176. The set of vehicle logged data 211 may represent typical situations or events that the autonomous vehicle 100 is expected to encounter in the one or more driving routes in the real world. In some implementations, each instance of vehicle logged data may be associated with a time stamp. The vehicle logged data may include time series log data, such as localization data, tracking data, and optionally include other vehicle sensor data and environmental data. For example, during a driving session of an AV 100, the vehicle control subsystem 150 may collect data at different points in time along with a record of when the data was acquired. As an example, each instance of time series log data may include a current location, orientation, and speed of the AV 100 based on the localization data. The tracking data may include tracking of objects external to the autonomous vehicle 100 describing their position(s), extent(s), orientation(s) categories, speed(s), and other tracking data or tracking predictions. Information on static objects (e.g., highway signs, lane markings, road surfaces, etc.) may also be logged. In some implementations, other forms of environmental data may also be logged (e.g., weather conditions, lighting conditions, visibility, etc.). In some implementations, the logged data generator 202 may process and convert the time stamped vehicle logged data 211 collected along a driving route in the real world into a set of route snippets or log snippets. Each log snippet in the set may include an event encountered by the autonomous vehicle 100. Depending on the event, the log snippet may include vehicle logged data before and/or after the event occurrence as well. For example, a log snippet having a duration of 30 seconds may include 10 seconds of vehicle logged data before and after the event occurrence. The logged data generator 202 may store the set of log snippets (e.g., set of logged data snippets of real world driving) under the logged data 211 in the data storage 280. For purposes of this disclosure, the terms “log snippet,” “original log,” and “logged data” are used interchangeably to mean the same thing, namely, ground truth driving data collected in association with the autonomous vehicle 100 under real-world driving conditions on public roads.

In some implementations, the logged data generator 202 may receive one or more user annotations (e.g., labels) for tagging each route snippet in the set of logged data snippets based on the presence of a particular operational environment (OE), vehicle maneuver (VM), or actor (A) or object and event detection and response (OEDR) in the route snippet. An OE element may characterize the operational environment of the AV 100, including the roadway types, geographic characteristics, speed ranges, weather and environmental conditions, traffic rules, location of operation, etc. A VM element may characterize the type of maneuvers the AV 100 itself initiates, typically having to do with navigation, such as entering and exiting a limited access roadway, initiating turns, changing lanes, stopping, parking, powering on and off, etc. An OEDR or actor (A) element may characterize the handling of external situations that the AV 100 encounters, including actors and objects, perception, planning, and implementation of the autonomous vehicle actions. In some implementations, the logged data generator 202 may generate and provide a user interface for a user to tag all relevant OE, VM, and OEDR elements in a log snippet. Each log snippet may include tags for speed limit, road type, lane description, direction and at least one vehicle maneuver. The logged data generator 202 stores the tags provided as annotations for each log snippet in the logged data 211. The tags make it easier to query the set of log snippets. For example, the set of log snippets may also be categorized based on the tags. In some implementations, the logged data generator 202 curates the training data set of log snippets and a categorization of OE, VM, and OEDR tags provided for each log snippet. The logged data generator 202 stores the training data set of log snippets in the data storage 280 and makes it accessible to train one or more machine learning models.

Example OE elements that may be tagged in a log snippet include but are not limited to time of day (e.g., morning, midday, evening, night, etc.), speed limit (e.g., 25 mph, 30 mph, 40 mph, etc.), road type or road surface (e.g., surface street, feeder or frontage road, highway, on ramp, off ramp, parking lot, etc.), straight traveling lanes (e.g., one lane straight, two lane straight, three lane straight, four lane straight, etc.), lane direction (e.g., one-way, two-way undivided, two-way divided, etc.), intersection (e.g., 4-way traffic light intersection, 3-way traffic light intersection, 2-way traffic light intersection, 1-way traffic light intersection, 4-way or all-way stop sign intersection, 2-way stop sign intersection, 1-way stop sign, 2-way uncontrolled intersection, 3-way uncontrolled intersection, 4-way uncontrolled intersection, etc.), type of traffic light (e.g., traffic light with protected left arrow, traffic light with protected right arrow, etc.), road elements (e.g., shoulder present on left, shoulder present on right, shoulder present on both sides, parallel parking lane present next to AV lane, bicycle lane, crosswalk, railroad crossing, fire lane, two lanes merging into one, etc.), etc.

Example VM elements that may be tagged in a log snippet include but are not limited to turns (e.g., turn unprotected left, turn right when the AV does not have a right of way, turn right on red at traffic light, turn protected right, turn protected left, turn right at a stop sign or when the AV has the right of way, turn left at a stop sign or when the AV has the right of way, U-turn, etc.), lane change (e.g., lane change to right, lane change to left), lane position (e.g., lane position occupied (starting from right most lane=1), and additional AV behaviors (e.g., merge, hold appropriate velocity for the speed limit of the road and/or modulate speed because of lead actor(s), stop, nudge, travel straight following a green traffic light, after stopping at a stop sign, or through uncontrolled intersection, etc.).

Example OEDR elements that may be tagged in a log snippet include but are not limited to presence or absence of actors/objects (e.g., pedestrians, motorcycle, cyclist, vehicles, foreign objects, construction zones, toll booths, police traffic stops, etc.) in or near AV path, occluded or un-occluded actors/objects in or near AV path, compliant or non-compliant actors/objects in or near AV path, type of actors/objects in or near AV path, motion (e.g., speed, velocity, acceleration, etc.) of actors/objects in or near AV path, etc.

The simulation management engine 204 may access, process, and manage a base set of simulation scenarios that is sufficiently diverse to model a set of real-world situations with which the behavior of the AV 100 can be tested. In some implementations, the simulation management engine 204 may access a base simulation scenario and convert the base simulation scenario into a plurality of simulation scenarios. For example, the simulation management engine 204 may use a parameter sweep to adjust a value of a parameter in a base simulation scenario through a defined range and generate configurations for a plurality of varying simulation scenarios. In another example, the simulation management engine 204 may use Monte Carlo sampling method for randomly sampling a value of a parameter in a base simulation from a probability distribution and generate configurations for a variety of simulation scenarios. As an example, changing the parameters in the base simulation scenario may include changing one or more configuration values of a vehicle platform parameter, a mapping parameter, a start gate, a start speed, actor (e.g., bicycle, pedestrian, etc.) placement, environmental parameter, or other autonomy parameters.

In some implementations, the simulation management engine 204 may convert the log file data of real-world driving accessible in the logged data 211 (e.g., generated by the logged data generator 202) in different ways to generate simulation data. The simulation data may represent an editable source of truth defining a number of simulation scenarios. The simulation management engine 204 may use one or more components of an instance of the logged data 211 to aid in creating at least one aspect of a simulation scenario. In some implementations, the simulation management engine 204 may use the vehicle logged data 211 as a source of data that is based on ground truth about real world driving situations to adjust the parameter values in the base simulation scenario for generating the plurality of varying simulation scenarios. For example, the simulation management engine 204 may use vehicle logged data 211 as an aid to generate a description including a behavior, vehicle configuration (e.g., AV location, platform, speed, or orientation), and sensor configuration of the AV (e.g., ego vehicle) and the environment including actors (e.g., other vehicles, traffic, pedestrians, and static objects) in a simulation scenario. However, more generally, in some implementations, other information available from the vehicle logged data 211 may be used as an aid in generating a simulation scenario. The vehicle logged data 211 may be generally used, in some implementations, as a resource to provide a source of real sensor data for a simulation task that requires a source of real sensor data.

The simulation management engine 204 may register a simulation scenario by generating a simulation identifier (e.g., simulation from log (SFL) identifier), assigning the simulation identifier to the simulation scenario, and storing the simulation scenario in the simulation registry 213 indexed by the simulation identifier in the data storage 280. For example, the simulation identifier may be a globally unique identifier (GUID). The simulation registry 213 may be a database storing currently and previously available simulation scenarios indexed by their corresponding simulation identifiers. In some implementations, the simulation management engine 204 may process a simulation scenario and derive one or more tags to associate with the simulation scenario in the simulation registry 214. For example, the tag may be based on one or more of a geography (e.g., San Francisco, New York, etc.), actors (e.g., other vehicles, bicycles, pedestrians, mobility scooters, motorized scooters, etc.), behaviors (e.g., lane change, merge, steering, etc.), location (e.g., four-way stop, intersection, ramp, etc.), status (e.g., deprecated, quarantined, etc.), actor vehicle make and model, sensor configurations, etc. In some implementations, the simulation management engine 204 may also receive one or more user annotations for tagging each simulation scenario in the simulation registry 213 based on a presence of OE, VM, and OEDR elements. For example, the simulation management engine 204 generates and provides a user interface for a user to tag all relevant OE, VM, and OEDR elements in a simulation scenario. The annotated tags make it easier to query the simulation registry 213 and select a simulation scenario. The simulation scenarios may also be categorized in the simulation registry 213 by the annotated tags. In some implementations, the simulation management engine 204 generates and provides a user interface to query the simulation registry 213 for selecting one or more simulation scenarios to execute in a simulation. For example, the query may include one or more phrases, such as “pedestrians near the AV path,” “speed limit=55 mph,” “4-way traffic light intersection,” etc. The simulation management engine 204 matches the query with the annotated tags associated with the simulation scenarios and retrieves the matching simulation scenarios from the simulation registry 213.

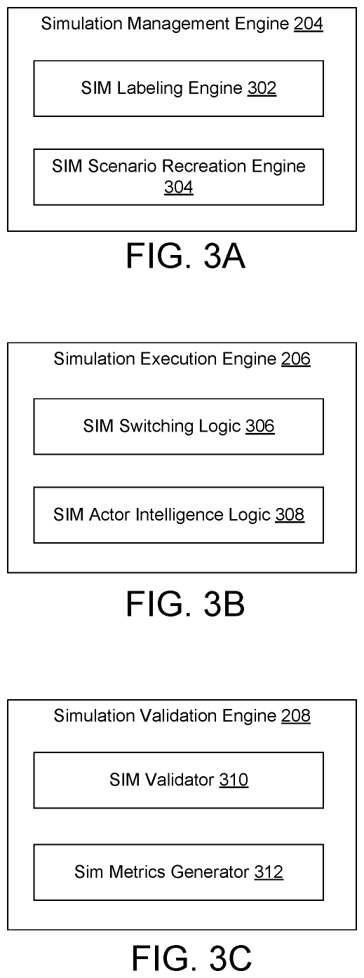

Referring to FIG. 3A, an example implementation of the simulation management engine 204 is illustrated in greater detail. The simulation management engine 204 may include a simulation (SIM) labeling engine 302 and a SIM scenario recreation engine 304.

In some implementations, the SIM labeling engine 302 may curate a list of simulation scenarios that include a suboptimal outcome in a traffic interaction involving the AV and a scripted actor. For example, the list of simulation scenarios may include existing simulation scenarios with observed AV-actor collisions curated from the simulation registry 213. A suboptimal outcome may refer to an autonomous driving behavior or decision made by the AV that, in the real world, may violate safety rules and regulations. Such safety violations by the AV may lead to accidents, collisions, or other dangerous situations that can cause harm or discomfort to passengers, other vehicles, or pedestrians. The degree of the suboptimal outcome may vary from anywhere between an outcome that is not the best (but acceptable) to an outcome that causes a severe failure in the AV's performance. Examples of suboptimal outcomes may include but are not limited to harsh acceleration, speeding, hard braking, slow downs, failure to yield, failure to recognize obstacles, failure to recognize traffic signs or traffic lights, close calls, violation of road boundaries, on-coming lane intrusion, lane drifting, collision, etc. The SIM labeling engine 302 may cooperate with the simulation execution engine 206 and the simulation validation engine 208 to collect a first set of labels for the list of simulation scenarios including scripted actors. The SIM labeling engine 302 may instruct the simulation execution engine 206 to run a simulation based on each simulation scenario from the list and collect human labels on whether a true positive suboptimal outcome in the AV's performance is observed in the simulation. In one example, a true positive AV-actor collision may be defined as a collision involving the AV and an actor where the AV's behavior or performance leads to a collision with the actor. A false positive AV-actor collision may be defined as a collision involving the AV and an actor where the actor's unreasonable behavior leads to a collision with the AV. In some implementations, the SIM labeling engine 302 may instruct the simulation execution engine 206 to execute a simulation for each scenario in the list of simulation scenarios using a degraded version of the motion planner for the AV to facilitate the collection of such true positive suboptimal outcome labels indicating the AV's performance. For example, the simulation execution engine 206 may configure such a poor motion planner for the AV by tuning one or more parameters in the software stack of the motion planner.

In some implementations, the SIM labeling engine 302 receives the simulation result and/or the simulation log based on the execution of the simulation for each scenario in the list of simulation scenarios from the simulation execution engine 206. The SIM labeling engine 302 processes the simulation log to generate label metadata to associate with each simulation scenario in the list. For example, a labeled simulation scenario may include a tuple of label metadata, such as: mission identifier, start time, and end time of the snippet; an identifier of the simulation scenario that is the source of the simulation; a commit hash (e.g., a unique identifier of the software version) of the motion planner used for the AV in the simulation scenario; a label indicating whether a suboptimal outcome in the AV's performance occurred; and suboptimal outcome descriptors including but not limited to a type of the suboptimal outcome (e.g., collision, hard braking, etc.), actor identifier of an actor involved in the suboptimal outcome, actor type of the actor involved in the suboptimal outcome, timestamp of the suboptimal outcome, severity of the suboptimal outcome, etc. The SIM labeling engine 302 may generate and provide a user interface for a human reviewer to submit the label that identifies the suboptimal outcome in the AV's performance for a simulation scenario. For example, the human reviewer may identify the AV-actor collision observed in the simulation of a particular simulation scenario as a true positive collision where the AV's behavior or performance is the cause of the collision with an actor. In another example, the human reviewer may identify the AV-actor collision observed in the simulation of a particular simulation scenario as a false positive collision where an actor's unreasonable behavior is the cause of the collision with the AV. The SIM labeling engine 302 stores the label metadata for each scenario in the list of simulation scenarios in the simulation registry 213 of the data storage 280.

The SIM labeling engine 302 may maintain the labeled dataset of the list of simulation scenarios to facilitate the development of intelligent simulation scenarios and the evaluation of actor behavior changes in improving the signal-to-noise ratio of one or more AV performance metrics obtained from the simulations of intelligent simulation scenarios. For example, the metrics may measure the instances of suboptimal outcomes in the AV's performance. The SIM labeling engine 302 may keep the label metadata unchanged for each labeled simulation scenario in the list for evaluation of actor behavior changes, such as the precision and/or recall of the metrics. There may be a restriction to only use a recent version of the motion planner for the AV in simulations. This can be problematic because a simulation run of the same simulation scenario using a different commit hash for the AV's motion planner may invalidate the original label of the simulation scenario. To safeguard against label invalidation, the SIM labeling engine 302 may collect fresh labels for each simulation scenario in the list every time the software version of the motion planner is updated. The SIM labeling engine 302 may default to the original label for the simulation scenario unless a change is detected in the new simulation run. In some implementations, the SIM labeling engine 302 may rely on an event detector that operates on an actor in the simulation based on the simulation scenario. The SIM labeling engine 302 checks the output of the event detector in the simulation log to see if its result is changed. For example, the result may be considered as changed when an actor that cut in front of the AV in the simulation of the originally labeled simulation scenario does not do so in the new simulation run because the new version of the motion planner causes the AV to accelerate and remain in front of the actor. If a change is detected, the SIM labeling engine 302 processes the simulation log to generate new label metadata for the simulation scenario. Example changes that may invalidate the original label may include but are not limited to metadata associated with the detected suboptimal outcome (e.g., collision, hard braking, harsh acceleration, etc.) in the new simulation run, such as the identifier of the actor involved in the suboptimal outcome, AV-relative location of collision point or of the actor, etc., invariants such as the capability under test in the simulation, etc.

The SIM scenario recreation engine 304 receives the labeled dataset of the list of simulation scenarios from the SIM labeling engine 302. The SIM scenario recreation engine 304 identifies a simulation scenario with a suboptimal outcome involving the AV from the list. The SIM scenario recreation engine 304 recreates the simulation scenario with intelligent actors to remove unrealistic actor behaviors that may have caused the suboptimal outcome and improve the quality of the simulation scenario. For example, the SIM scenario recreation engine 304 may identify a simulation scenario having a label metadata indicating a presence of a false positive AV actor collision and recreate the simulation scenario to use intelligent actors. In some implementations, the SIM scenario recreation engine 304 may receive a user request to update a simulation scenario including a suboptimal outcome involving the AV to use intelligent actors in place of scripted actors. In some implementations, the SIM scenario recreation engine 304 processes the simulation log of an existing simulation scenario from the labeled dataset of the list of simulation scenarios and identifies the actor(s) involved in the suboptimal outcome. The SIM scenario recreation engine 304 automatically constructs an intelligent simulation scenario corresponding to the existing simulation scenario by replacing the actor(s) involved in the false positive AV-actor collision with intelligent actors.

The SIM scenario recreation engine 304 replaces one or more existing non-AV actors in the simulation scenario with intelligent non-AV actors. For example, the SIM scenario recreation engine 304 replaces existing scripted actors in the simulation scenario with intelligent actors, such as intelligent path follower (IPF) actors. A scripted actor in the existing simulation scenario is an actor that follows a predefined temporal trajectory in the simulation. Although the scripted actor may possess good accuracy in terms of replaying a trajectory from the original log, it may have bad responsiveness in terms of adapting to the planned behavior exhibited by the AV in the simulation. For example, the scripted actor can rear-end the AV or conduct a lane change even though the AV is already present or going to be present in the conflicted lane. As such, the use of scripted actors reduces the signal-to-noise ratio for metrics that measure suboptimal outcomes and may not facilitate accurately evaluating the performance of the AV. The IPF actor is a type of path follower (PF) actor. A PF actor is an integrated actor that follows a predefined spatial path. The PF actor does not possess any intelligence while the IPF actor can be configured to possess different intelligence capabilities that affect its motion as described herein. The SIM scenario recreation engine 304 may retrieve a platform file of the existing simulation scenario from the simulation registry 213 in the data storage 280 and update the platform file by replacing the parameters associated with scripted actors with IPF actors while preserving the rest of the parameters. This ensures that the recreated simulation scenario is generally consistent with the existing simulation scenario. That is, parameters other than IPF actors are preserved in the recreated simulation scenario. Such a recreated simulation scenario using intelligent actors may be referred to as an intelligent simulation scenario.

The intelligent actors replacing the scripted actors in the intelligent simulation scenario are just as accurate in replaying the logged trajectory from the original log in the simulation. The SIM scenario recreation engine 304 enables a mode within the intelligent actors in the intelligent simulation scenarios to selectively deviate from respective logged trajectories during a simulation run. The SIM scenario recreation engine 304 equips the intelligent actors in the intelligent simulation scenario to selectively deviate from the logged trajectory in response to new environmental changes, such as the planned trajectory of the AV in the simulation. For example, the IPF actor in the intelligent simulation scenario may be equipped with a set of capabilities to selectively deviate from logged trajectory, such as merge interaction reasoning, adaptive cruise control (ACC), intersection navigation handling, collision avoidance, etc. to avoid an unrealistic behavior that may cause a suboptimal outcome in the performance of the AV in the simulation. This improves the precision of the metrics measuring instances of suboptimal outcomes in the AV's performance as determined from the simulation based on the intelligent simulation scenario while maintaining the recall of the metrics.

The SIM scenario recreation engine 304 enables, by default, the ability to selectively deviate from logged trajectory for all non-AV actors in the intelligent simulation scenario. In some implementations, the SIM scenario recreation engine 304 may receive user input selecting a particular non-AV actor in the intelligent simulation scenario to be equipped with the ability to selectively deviate from logged trajectory. The SIM scenario recreation engine 304 constructs the intelligent simulation scenario with the selected non-AV actor equipped with the ability to selectively deviate from logged trajectory. In some other implementations, the SIM scenario recreation engine 304 may receive user input opting out one or more non-AV actors in the intelligent simulation scenario from being able to deviate from logged trajectory. For example, the user wanting to test the AV in a simulation may have observed an actor that behaved in a non-compliant way (e.g., aggressive driving) in the original log snippet with no AV-actor collision. In an intelligent simulation scenario corresponding to this log snippet, the user may not wish to equip this non-compliant actor with the ability to deviate from logged trajectory in the simulation. Instead, the user may wish to preserve the non-compliant behavior of the actor in order to induce the collision with the AV or to test the behavioral response of the AV to the non-compliant actor behavior in the simulation. The SIM scenario recreation engine 304 constructs the intelligent simulation scenario with select actors opted out of the ability to deviate from logged trajectory during simulation.

Once the deviation from logged trajectory is initiated for an intelligent actor in a simulation, the intelligent actor may start diverging significantly from its original logged trajectory which then fails to preserve the original scene of the simulation scenario. To rectify this, the SIM scenario recreation engine 304 optimizes one or more parameters associated with the actor behavior models used within the intelligent actors to follow the original logged trajectory when the simulation scenario is recreated. This actor model parameter optimization improves the log trajectory reproducibility of the intelligent actor in the simulation. The SIM scenario recreation engine 304 uses an optimization technique to optimize actor behavior model parameters and/or the intelligent driver model (IDM) parameters for the intelligent actors in the corresponding intelligent simulation scenario to maintain a minimum scene divergence from the original log snippet. For example, the SIM scenario recreation engine 304 may use a non-linear least squares optimization method that accounts for gradient and curvature in the optimization of the actor behavior model parameters to better fit the logged trajectory. In some implementations, the SIM scenario recreation engine 304 cooperates with the machine learning engine 166 to train the actor behavior models using a training data set of log snippets. For example, the actor behavior models may be trained using a plurality of logged trajectories of actors in real-world driving data.

The SIM scenario recreation engine 304 may generate a list of intelligent simulation scenarios corresponding to the labeled dataset of the list of simulation scenarios maintained by the SIM labeling engine 302. The SIM scenario recreation engine 304 may identify a batch of simulation scenarios and convert the batch into intelligent simulation scenarios. For example, the SIM scenario recreation engine 304 may identify a batch of frequently used and/or recently used simulation scenarios (e.g., valuable simulation scenarios) and convert all of the scenarios in the batch into intelligent simulation scenarios at once. The SIM scenario recreation engine 304 may cooperate with the simulation execution engine 206 and the simulation validation engine 208 to validate the intelligent simulation scenario from the list of intelligent simulation scenarios. Once the intelligent simulation scenario is validated, the SIM scenario recreation engine 304 may deploy the intelligent simulation scenario as a default for use in place of the existing simulation scenario.

The SIM labeling engine 302 may cooperate with the simulation execution engine 206 and the simulation validation engine 208 to collect a second set of labels for the list of intelligent simulation scenarios for evaluating the actor behavior changes against the list of non-intelligent simulation scenarios. For example, the SIM labeling engine 302 may instruct the simulation execution engine 206 to run a simulation based on each intelligent simulation scenario from the list and collect human labels on whether a true positive suboptimal outcome is observed in the simulation. In some implementations, the SIM labeling engine 302 may instruct the simulation execution engine 206 to execute the simulation for each scenario in the list of intelligent simulation scenarios using a degraded version of the motion planner for the AV to facilitate the collection of true positive suboptimal outcome labels. It should be understood that evaluating the actor behavior change against a handicapped motion planner of the AV will not provide the same exact signal on maintaining recall of true positive safety violation for the AV compared to evaluating against the latest version of the normal motion planner. The SIM labeling engine 302 may be configured to continuously collect true positive safety violations using the latest motion planner version of the AV to ensure that the recall of the metrics in intelligent simulation scenarios do not degrade. The SIM scenario recreation engine 304 stores the list of intelligent simulation scenarios in the simulation registry 213 of the data storage 280.

The simulation execution engine 206 may execute a simulation for the set of control subsystems 150 of the autonomous vehicle 100 based on one or more simulation scenarios in the simulation registry 213. For example, the simulation scenarios may correspond to perception simulation scenarios, motion planning simulation scenarios, vehicle detection and tracking scenario, etc. In some implementations, the simulation management engine 204 sends a simulation identifier to the simulation execution engine 206. The simulation execution engine 206 uses the simulation identifier to fetch a configuration of a matching simulation scenario from the simulation registry 213 and executes a simulation based on the fetched simulation scenario configuration. The simulation execution engine 206 may create a run identifier (run ID) to associate with an execution (run) of the simulation. In some implementations, the simulation execution engine 206 may create a batch of a plurality of simulation scenario variations and execute the batch in a single execution. In such implementations, the simulation execution engine 206 may create a batch identifier (batch ID) to associate with the batch execution. The simulation execution engine 206 may generate a simulation result and/or a simulation log during the execution of the simulation and store it in the simulation log 215. In some implementations, the simulation result and/or a simulation log may be one or more formatted messages including or encoded with state information of the AV 100 and other actors observed in the simulation. For example, the state information may include detection of events associated with the AV 100, such as collisions, hard braking, slow downs, and other potential critical events observed in the simulation run. The simulation log 215 may be a database storing a historical log of simulation runs indexed by corresponding run ID and/or batch ID. In some implementations, the simulation execution engine 206 generates one or more formatted messages reflecting events observed in the simulation based on the simulation scenario in real time during execution of the simulation for streaming to the simulation validation engine 208.

Referring to FIG. 3B, an example implementation of the simulation execution engine 206 is illustrated in greater detail. The simulation execution engine 206 may include SIM switching logic 306 and SIM actor intelligence logic 308 to facilitate an execution of a simulation based on the intelligent simulation scenario.

The SIM switching logic 306 receives the list of intelligent simulation scenarios from the SIM scenario recreation engine 304. The SIM switching logic 306 determines an intelligent simulation scenario from the list and executes a simulation based on the intelligent simulation scenario. The intelligent simulation scenario may include one or more non-AV intelligent actors, such as IPF actors that may selectively choose to exhibit different intelligent behaviors in the simulation. For purposes of this disclosure, the intelligent behavior may refer to the capability of the intelligent actor to selectively deviate from a logged trajectory in response to a change in AV behavior (e.g., a planned trajectory of the AV) and/or another intelligent actor behavior during simulation.

Different intelligent behaviors affect the motion of the IPF actor in the simulation under specific conditions. There may be limits placed on the intelligent behavior of the IPF actor such that its behavior approximates that of an average human driver in the real world. In some implementations, the limits on the intelligent behavior may be physical. For example, the limits may specify a maximum rate of acceleration, a minimum safe following distance to maintain, a minimum distance to travel before initiating a lane change, etc. The IPF actor may have a predefined path to follow that is composed of a sequence of connected route edges. In addition, the IPF actor may have a sequence of control points that lie along those route edges. The control points specify a desired speed for the IPF actor at different points along its route. In the simulation, the IPF actor perceives the world in the orthogonal curvilinear coordinate (OCC) frame of reference defined by its route, rather than in Cartesian coordinates. For example, the IPF actor perceives other actors' positions in the simulation in terms of their longitudinal, lateral, and loft displacements along its own route. The IPF actor in an intelligent simulation scenario may have access to the ground truth acceleration profile that the original actor exhibits in the original log. In some implementations, the SIM actor intelligence logic 308 may selectively choose to enable intelligent behavior in the acceleration of the IPF actor along the longitudinal component of its OCC frame.

The SIM switching logic 306 monitors the execution of the simulation to determine whether a behavior-switching condition for a non-AV actor is satisfied. The behavior-switching condition for the non-AV actor may be evaluated in association with the change in behavior (e.g., logged trajectory) of the AV and/or another non-AV actor in the simulation. The SIM switching logic 306 uses the behavior-switching condition to identify a time step at which to switch the non-AV actor from trajectory-following to an intelligent behavior in the simulation. In some implementations, the behavior switching condition evaluated by the SIM switching logic 306 may be defined by one or more of a traffic conflict involving the non-AV actor and the AV, a divergence threshold between the planned trajectory of the AV and its logged trajectory (e.g., divergence threshold measured in meters), a current distance threshold between the intelligent AV and intelligent non-AV actors (e.g., distance threshold measured in meters), a context of the scene involving other non-AV actors in the simulation, a change in the state of dynamic elements (e.g., pedestrians, animals, birds, traffic lights, weather, time of day, etc.) other than the non-AV actors in the simulation, a presence of static elements (e.g., road signs, unexpected obstacles, traffic barricades, etc.), a proximity to traffic infrastructure (e.g., proximity of the non-AV actor to an intersection ahead, proximity of the non-AV actor to a merge point ahead, etc.) in the simulation, etc. If the behavior-switching condition is satisfied, the SIM switching logic 306 instructs the SIM actor intelligence logic 308 to modify the behavior of the non-AV actor to deviate from its logged trajectory in the simulation.

The SIM switching logic 306 determines a logged future trajectory of the non-AV actor. For example, the SIM switching logic 306 queries the original log file for a future trajectory of the non-AV actor in the simulation. The SIM switching logic 306 estimates a predicted future trajectory of the AV in the simulation. For example, the SIM switching logic 306 estimates the predicted future trajectory of the AV by querying the AV for its predicted state in the simulation. The SIM switching logic 306 uses the logged future trajectory of the non-AV actor and the predicted future trajectory of the AV to determine whether the non-AV actor is going to have a traffic conflict with the AV at a future point in time and space in the simulation. Specifically, the SIM switching logic 306 reframes the predicted future trajectory of the AV onto the OCC frame of reference of the non-AV actor to determine the position of the AV in terms of its longitudinal, lateral, and loft displacement along the route of the non-AV actor. The SIM switching logic 306 iteratively steps forward along the reframed predicted future trajectory of the AV at a given discretization level and up to a given look ahead time in the future. In one example, the discretization level may be defined by a discrete time step. The SIM switching logic 306 determines whether the non-AV actor is going to have a traffic conflict with the AV at each discretization level. For example, the traffic conflict may include an upcoming collision, a merge navigation, an intersection navigation, following in the same lane, etc. If there is going to be a traffic conflict in the simulation, the SIM switching logic 306 identifies a group including the non-AV actor and the AV in the simulation as part of the traffic conflict. The SIM switching logic 306 sends the group to the SIM actor intelligence logic 308 for selectively enabling an intelligent behavior for an intelligent actor in the group.

The SIM actor intelligence logic 308 receives the group associated with the traffic conflict from the SIM switching logic 306, determines an intelligent non-AV actor in the group, and modifies the behavior of the non-AV actor to deviate from its logged trajectory to avoid an unrealistic behavior that may cause a suboptimal outcome involving the AV in the simulation. The SIM actor intelligence logic 308 uses one or more machine learning models associated with an intelligence of the non-AV actor to modify the behavior of the non-AV actor. For example, the SIM actor intelligence logic 308 uses an actor behavioral model to modify an acceleration of the non-AV actor along the longitudinal component of its OCC frame in the simulation. In some implementations, the SIM actor intelligence logic 308 may have access to different machine learning behavioral models associated with the non-AV actor that can initiate different intelligent behaviors in the simulation. The SIM actor intelligence logic 308 may choose a minimum longitudinal acceleration for the non-AV actor from among the different intelligent behaviors. For example, the SIM actor intelligence logic 308 chooses the minimum acceleration as a heuristic for the safest among the different intelligent behaviors.

Consider that the traffic conflict is associated with traveling in the same conflicted lane, the SIM actor intelligence logic 308 determines an acceleration for the non-AV actor that maintains a safe following distance behind the lead vehicle (e.g., AV).

Consider that the traffic conflict is associated with an upcoming collision, the SIM actor intelligence logic 308 determines an acceleration for the non-AV actor that prevents a collision with the AV.

Consider that the traffic conflict is associated with navigating a merge, the SIM actor intelligence logic 308 determines whether the non-AV actor has to yield to the AV in the merge navigation. If the non-AV actor has to yield, the SIM actor intelligence logic 308 determines an acceleration for the non-AV actor to yield to the AV.

Consider that the traffic conflict is associated with navigating an intersection, the SIM actor intelligence logic 308 determines whether the non-AV actor has a right of way in the intersection navigation. If the AV has the right of way instead, the SIM actor intelligence logic 308 determines an acceleration for the non-AV actor to stop at the stop line of the intersection, and to resume driving when it is the non-AV actor's turn to go through the intersection.

In the implementations where more than one of the above-described traffic conflicts is a possibility, the SIM actor intelligence logic 308 chooses a minimum among the different accelerations as the acceleration of the non-AV actor in the simulation.

Once this first non-AV actor has selectively deviated from its logged trajectory, there may be a cascading effect where other non-AV actors in the simulation will have to adapt their behavior to the first non-AV actor. For example, a second non-AV actor may be following its logged trajectory behind the first non-AV actor and consequently become a part of the group involved in the traffic conflict in the simulation. The SIM switching logic 306 determines whether a behavior-switching condition for a second non-AV actor in association with the first non-AV actor is satisfied. If it is satisfied, the SIM actor intelligence logic 308 proceeds to modify the behavior of the second non-AV actor to deviate from its logged trajectory in the simulation.

To further demonstrate the selective enabling of intelligent behaviors within non-AV actors in simulations, an example implementation of enabling merge navigation intelligence in non-AV actors is described in detail below.

The SIM switching logic 306 detects whether there are merging actors ahead in a simulation. For example, the merging actors may include the AV and non-AV actors. The SIM switching logic 306 queries the AV (e.g., merging actor) for its predicted states in the simulation and estimates a predicted future trajectory. The SIM switching logic 306 reframes the predicted future trajectory of the AV onto the OCC frame of reference of a non-AV actor involved in the merge traffic conflict. The SIM switching logic 306 iteratively steps forward along the reframed predicted future trajectory of the AV at a given discretization level up to a given look ahead time in the future in the simulation. For each predicted state in this discretization, the SIM switching logic 306 determines whether the AV overlaps with the logged future trajectory of the non-AV actor. That is, the SIM switching logic 306 determines whether following conditions are met. A first condition checks whether an absolute value of the lateral offset of the AV in the non-AV actor's OCC frame is smaller than a sum of a first multiple of the width of the non-AV actor and a second multiple of the width of the AV actor. A second condition checks whether the heading of the predicted state of the AV aligns with the direction of the non-AV actor's path. The second condition is checked to ensure that non-merging crossing trajectories are not considered merges. If the predicted state of the AV satisfies the above conditions, the SIM switching logic 306 detects a merge traffic conflict ahead in the simulation. In some implementations, the SIM switching logic 306 may use a model based on geometric heuristics to detect merging actors ahead in the simulation.

The SIM actor intelligence logic 308 may use a machine learning decision model to determine a discrete decision for the non-AV actor involved in a traffic conflict. For example, in the implementation of the merge navigation intelligence, the SIM actor intelligence logic 308 uses a merge decision model to determine whether the non-AV actor has to yield to the merging actor (e.g., AV) in the merge traffic conflict that is detected by the SIM switching logic 306. Other example discrete decisions output by the decision model may include whether the non-AV actor has to follow another intelligent actor, lead another intelligent actor, be in tandem with another intelligent actor, etc. The SIM actor intelligence logic 308 inputs the instantaneous features of the non-AV actor's current state and/or predicted state and the merging actor's current state and/or predicted state into the merge decision model to output a probability that the non-AV actor has to yield to the merging actor. For example, the current state and/or predicted state may include speed, acceleration, distance to merge point, etc. and the merge decision model may be a logistic regression model with a number of hidden layers between the input features and the logistic output. In some implementations, the SIM actor intelligence logic 308 may also input other contextual input features, such as lane precedence, speed limits, information about other actors, etc. into the merge decision model for generating the logistic output. The output decision of the merge decision model can be parameterized by an assertiveness parameter. The value of this parameter varies between 0.0 (always yield) to 1.0 (never yield) and represents the confidence threshold that the merge decision model has on the yield decision for the non-AV actor.

The SIM actor intelligence logic 308 may use a machine learning behavioral model to modify a behavior of the non-AV actor involved in a traffic conflict. The behavioral model may output the continuous action/reaction modifying the behavior of the non-AV actor based on the discrete decision of the decision model. For example, in the implementation of the merge navigation intelligence, the SIM actor intelligence logic 308 uses a merge behavioral model of the non-AV actor to determine a merging acceleration for the non-AV actor that is consistent with the yield decision of the merge decision model. In some implementations, the SIM actor intelligence logic 308 adapts a version of the IDM used for implementing ACC behavior to determine the merging acceleration of the non-AV actor. If the yield decision is to not yield, the SIM actor intelligence logic 308 ignores the merging actor and uses the regular acceleration profile of the non-AV actor in the simulation. If the yield decision is to yield, the SIM actor intelligence logic 308 reframes a current state of the merging actor onto the OCC frame of reference of the non-AV actor. The SIM actor intelligence logic 308 determines the merging acceleration by projecting the pose of the merging actor onto the route of the non-AV actor and using other data, such as the current speed of the non-AV actor, a desired speed of the non-AV actor, a speed of the merging actor, the headway between the non-AV actor and the merging actor, etc. The current speed of the non-AV actor is its longitudinal speed in its OCC frame. The speed of the merging actor is the merging actor's longitudinal speed along the OCC frame of the non-AV actor. The desired speed of the non-AV actor is the speed specified at the next control point along the non-AV actor's route. The headway between the non-AV actor and the merging actor is the difference between the longitudinal offset of the non-AV actor on its OCC frame and the longitudinal offset of the merging actor on the OCC frame of the non-AV actor. In some implementations, the SIM actor intelligence logic 308 inputs the instantaneous features of the non-AV actor's current state and/or predicted state and the merging actor's current state and/or predicted state into the merge behavioral model of the non-AV actor to determine the merging acceleration. For example, the merge behavioral model may be trained on logged trajectories of actors in real-world driving data.

The simulation validation engine 208 may monitor execution of the simulation based on a plurality of simulation scenarios by the simulation execution engine 206 and validate the corresponding simulation scenarios. The simulations often have many different modules and during execution, each of the modules generates and sends several messages with state information about the simulation execution. The execution of the simulation by the simulation execution engine 206 may be configured to forward the messages to the simulation validation engine 208 for processing in real time or with some amount of predetermined latency. In some implementations, the simulation validation engine 208 may process simulation result and/or a simulation log 215 after the simulation(s) have executed. The simulation validation engine 208 processes the messages and automatically detects occurrence of one or more events during the execution of the simulation. The simulation validation engine 208 may generate and store validation results associated with validating the simulation scenario in the simulation log 216. In some implementations, the simulation management engine 204 analyzes the validation results and identifies the events or other interesting behaviors observed in the simulation based on the simulation scenario. The simulation management engine 204 may map back the analysis of validation results to the simulation data 212 to reconfigure and recreate a variation of the simulation scenario with intelligent actors. The intelligent simulation scenario may be executed again in a simulation by the simulation execution engine 206 and validated by the simulation validation engine 208.

Referring to FIG. 3C, an example implementation of the simulation validation engine 208 is illustrated in greater detail. The simulation validation engine 208 may include SIM validator 310 and SIM metrics generator 312 to validate a plurality of simulation scenarios.

The SIM validator 310 receives a plurality of messages broadcast by the simulation execution engine 206. The messages may correspond to a time series of messages originating during an execution of one or more simulations. In some implementations, the SIM validator 310 may process the time series data up until a certain point in time (latching point) or a certain condition is satisfied, and ignore messages afterwards, based on the time series up to that time. The SIM validator 310 may be configured with a validation condition. The validation condition may be associated with checking for a suboptimal outcome in a traffic interaction involving the AV and other actors in the simulation. Example suboptimal outcomes may include but are not limited to harsh acceleration, speeding, hard braking, slow downs, failure to yield, failure to recognize an obstacle, failure to recognize a road sign, close calls, violation of road boundaries, on-coming lane intrusion, lane drifting, collision, etc. The SIM validator 310 performs a validation check on the received messages. The validation check performed by the SIM validator 310 determines whether a value of the message satisfies the constraints specified by a validation condition. The components of the validation condition may use Boolean operators or operators, such as ‘=,’ ‘>,’ “=>’, ‘<=’, and ‘<.’ The Boolean and other operators may be binary (e.g., two operands), but need not necessarily require binary operators, e.g., a <=x<=b, or (x AND y AND z). The SIM validator 310 generates a status message indicating whether the validation check on the processed message was successful (pass) or not (fail) and sends the status message to the SIM metrics generator 312. In other words, the SIM validator 310 verifies whether its condition has been satisfied.

The SIM validator 310 may implement a suboptimal outcome validator that facilitates flagging of a potential true positive suboptimal outcome in the simulation. The suboptimal outcome validator receives state messages including information about the state of bounding boxes denoting actors in the simulation and determine whether a validation condition is satisfied. For example, a collision validator may check the overlap between a bounding box of the AV and a bounding box of one or more other actors in the simulation. The collision validator determines a collision has occurred if an overlap is detected between the bounding boxes of autonomous vehicles and the other actors. The collision validator generates a status message indicating whether the collision check on the processed messages was successful (collision detected) or fail (no collision detected) and sends the status message to the SIM metrics generator 312.

The SIM validator 310 may implement a scene divergence validator that validates the scene divergence of actors from logged trajectory in the simulation. The scene divergence validator receives state messages including the speed, distance, and time of travel associated with actors observed in the simulation before and after the actor intelligence is selectively enabled. The scene divergence validator determines whether the actor scene divergence is above or below a nominated threshold after the actor intelligence is selectively enabled. For example, the threshold for scene divergence may be 100 meters. The scene divergence validator determines that the actor in the simulation has diverged from the original log if the scene divergence is above the threshold. The scene divergence validator generates a status message indicating whether the scene divergence check on the actors was successful (scene divergence above threshold detected) or fail (scene divergence below threshold detected) and sends the status message to the SIM metrics generator 312.

The SIM metrics generator 312 determines values of one or more performance metrics in association with the actors in the simulation scenarios from the execution of the simulations. The performance metric may be a statistic determined for the AV 100 along multiple AV performance dimensions, such as safety, comfort, etc. The SIM metrics generator 312 receives the status messages from the SIM validator 310 and determines a metric in association with the AV's performance based on the execution of the simulation. The metric is used to assess the performance of the AV's capability under test, such as perception, path planning, or vehicle control. The metric measures the number of suboptimal outcomes involving the AV that occur during the simulation. In one example, the SIM metrics generator 312 receives the collision-related status messages from the SIM validator 310 and determines a collision metric for the AV-actor collisions based on the execution of the simulation. The collision metric measures the number of the AV-actor collisions. In another example, the SIM metrics generator 312 receives the scene divergence-related status messages from the SIM validator 310 and determines a scene divergence metric in association with the actors based on the execution of the simulation. The scene divergence metric measures how the actors are diverging from their logged trajectory quantitatively. The SIM metrics generator 312 may be configured to separate out the scene divergence metric before and after the actor intelligence is selectively enabled in the simulation.

It should be understood that the AV-actor collision metric generated by the SIM metrics generator 312 is a sum of true positive AV-actor collisions and false positive AV-actor collisions. In some implementations, the SIM metrics generator 312 receives the labels collected for true positive AV-actor collision on the first list of simulation scenarios using scripted actors (non-intelligent simulation scenarios) and the second list of simulation scenarios using intelligent actors (intelligent simulation scenarios). The SIM metrics generator 312 calculates precision and recall of the collision metric associated with both lists of simulation scenarios for evaluation. The precision of the collision metric may be defined as the fraction of true positive AV-actor collisions among all detected AV-actor collisions (i.e., sum of true positive AV-actor collisions and false positive AV-actor collisions). The recall of the collision metric may be defined as the fraction of true positive AV-actor collisions that were detected among the actual number of true-positive AV-actor collisions (i.e., sum of true positive AV-actor collisions and false negative AV-actor collisions). The SIM metrics generator 312 determines that the precision of the collision metric for the list of intelligent simulation scenarios is improved compared to the list of non-intelligent simulation scenarios. This is because the number of false positive AV-actor collisions is reduced by enabling actors to avoid unrealistic collisions. The recall of the collision metric is at least maintained for the list of intelligent simulation scenarios.

As shown in FIG. 2, the computing system 172 includes a machine learning engine 166 to train one or more machine learning models 224. For example, the one or more machine learning models 224 may be actor behavior models. In some implementations, the machine learning engine 166 receives the training data from the intelligent SFL system 160 for training the machine learning model 224. For example, the training data may include features from the set of log snippets and a categorization of OE, VM, and OEDR tags provided for each log snippet.

As shown in FIG. 2, in some implementations, once the intelligent SFL system 160 has validated the intelligent simulation scenarios as suitable for training the machine learning model 224, the machine learning engine 166 may train the machine learning model 224 using the intelligent simulation scenarios as training examples. In some implementations, the absence of assignment of intelligent actors to the simulation scenario may disqualify the corresponding simulation scenario and its simulation data for use in training the machine learning model 224 of the autonomous vehicle 100. In some implementations, the machine learning model 224 is a neural network model and includes a layer and/or layers of memory units where memory units each have corresponding weights. A variety of neural network models can be utilized including feed forward neural networks, convolutional neural networks, recurrent neural networks, radial basis functions, other neural network models, as well as combinations of several neural networks. Additionally, or alternatively, the machine learning model 224 can represent a variety of machine learning techniques in addition to neural networks, for example, support vector machines, decision trees, Bayesian networks, random decision forests, k-nearest neighbors, linear regression, least squares, other machine learning techniques, and/or combinations of machine learning techniques.

Machine learning models 224 may be trained for a variety of autonomous vehicle tasks including determining a target autonomous vehicle location, generating one or more signals to control an autonomous vehicle, tracking or identifying objects within the environment of an autonomous vehicle, etc. For example, a neural network model may be trained to identify traffic lights in the environment with the autonomous vehicle 100. As a further example, a neural network model may be trained to predict the make and model of other vehicles in the environment with the autonomous vehicle 100. In many implementations, neural network models may be trained to perform a single task. In other implementations, neural network models may be trained to perform multiple tasks.

The machine learning engine 166 may generate training instances from the simulation scenarios to train the machine learning model 224. A training instance can include, for example, an instance of simulated autonomous vehicle data where the autonomous vehicle 100 can detect a stop sign using the simulated sensor data from one or more sensors and a label corresponding to a simulated output corresponding to bringing the autonomous vehicle to a stop in the simulation scenario. The machine learning engine 166 may apply a training instance as input to machine learning model 224. In some implementations, the machine learning model 224 may be trained using any one of at least one of supervised learning (e.g., support vector machines, neural networks, logistic regression, linear regression, stacking, gradient boosting, etc.), unsupervised learning (e.g., clustering, neural networks, singular value decomposition, principal component analysis, etc.), or semi-supervised learning (e.g., generative models, transductive support vector machines, etc.). Additionally, or alternatively, machine learning models in accordance with some implementations may be deep learning networks including recurrent neural networks, convolutional neural networks (CNN), networks that are a combination of multiple networks, etc. For example, the machine learning engine 166 may generate a predicted machine learning model output by applying training input to the machine learning model 224. Additionally, or alternatively, the machine learning engine 166 may compare the predicted machine learning model output with a machine learning model known output (e.g., simulated output in the simulation scenario) from the training instance and, using the comparison, update one or more weights in the machine learning model 224. In some implementations, one or more weights may be updated by backpropagating the difference over the entire machine learning model 224.

The machine learning engine 166 may test a trained machine learning model according to some implementations. The machine learning engine 166 may generate testing instances using the simulation scenario and the simulated autonomous vehicle in the simulation scenario performing the specific autonomous vehicle task for which the machine learning model 224 is trained. The machine learning engine 166 may apply a testing instance as input to the trained machine learning model 224. A predicted output generated by applying a testing instance to the trained machine learning model 224 may be compared with a known output for the testing instance (i.e., a simulated output observed in the simulation) to update an accuracy value (e.g., an accuracy percentage) for the machine learning model 224.

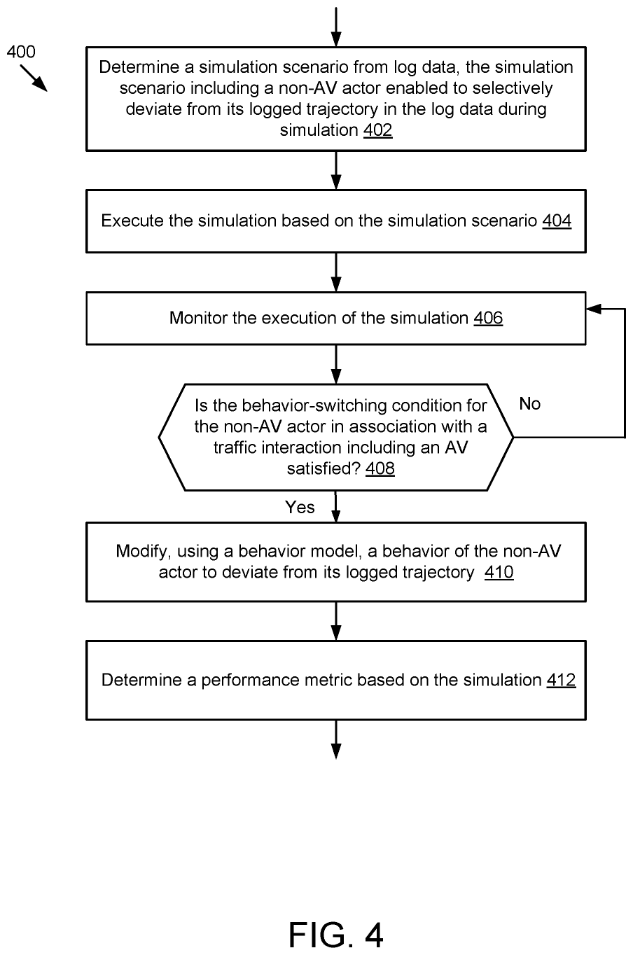

Referring now to FIG. 4, a method 400 of evaluating the performance of an autonomous vehicle in accordance with some implementations is illustrated. The method 400 may be a sequence of operations or process steps performed by a system of one or more computers in one or more locations, including, for example, the intelligent SFL system 160 in the computing system 172 of FIG. 2, by another computer system that is separate from the intelligent SFL system 160 in FIG. 2, or any combination thereof. Moreover, while in some implementations, the sequence of operations may be fully automated, in other implementations some steps may be performed and/or guided through human intervention. Furthermore, it will be appreciated that the order of operations in the sequence may be varied, and that some operations may be performed in parallel and/or iteratively in some implementations.

In block 402, the system determines a simulation scenario from log data, the simulation scenario including a non-AV actor. The non-AV actor is enabled to selectively deviate from its logged trajectory in the log data during simulation. For example, the non-AV actor may be an IPF actor with a set of capabilities to selectively deviate from logged trajectory, such as merge interaction reasoning, adaptive cruise control (ACC), intersection navigation handling, collision avoidance, etc.

In block 404, the system executes a simulation based on the simulation scenario.

In block 406, the system monitors the execution of the simulation.

In block 408, the system determines whether a behavior-switching condition for the non-AV actor in association with a traffic interaction including an AV is satisfied based on the monitoring. The behavior-switching condition for the non-AV actor is evaluated in association with the change in behavior (e.g., logged trajectory) of the AV and/or another non-AV actor in the simulation. The system uses the evaluation of the behavior-switching condition to identify a time step at which to switch the non-AV actor from trajectory-following to an intelligent behavior in the simulation.

If in block 408, the system determines that the behavior-switching condition for the non-AV actor in association with the traffic interaction including the AV is not satisfied, then the system loops back to block 406. The system continues to monitor the execution of the simulation.

On the other hand, if in block 408, the system determines that the behavior-switching condition for the non-AV actor in association with the traffic interaction including the AV is satisfied, then the system proceeds to block 410.

In block 410, the system modifies a behavior of the non-AV actor to deviate from its logged trajectory using a behavior model. For example, the non-AV actor chooses to selectively deviate from a logged trajectory in response to a change in AV behavior (e.g., a planned trajectory of the AV deviating from its logged trajectory in the log data) and/or another intelligent actor behavior during simulation.

In block 412, the system determines a performance metric based on the simulation. The performance metric is used to assess the performance of the AV's capability under test, such as perception, path planning, or vehicle control. The performance metric measures the number of suboptimal outcomes in the performance of the AV that occur during the simulation.

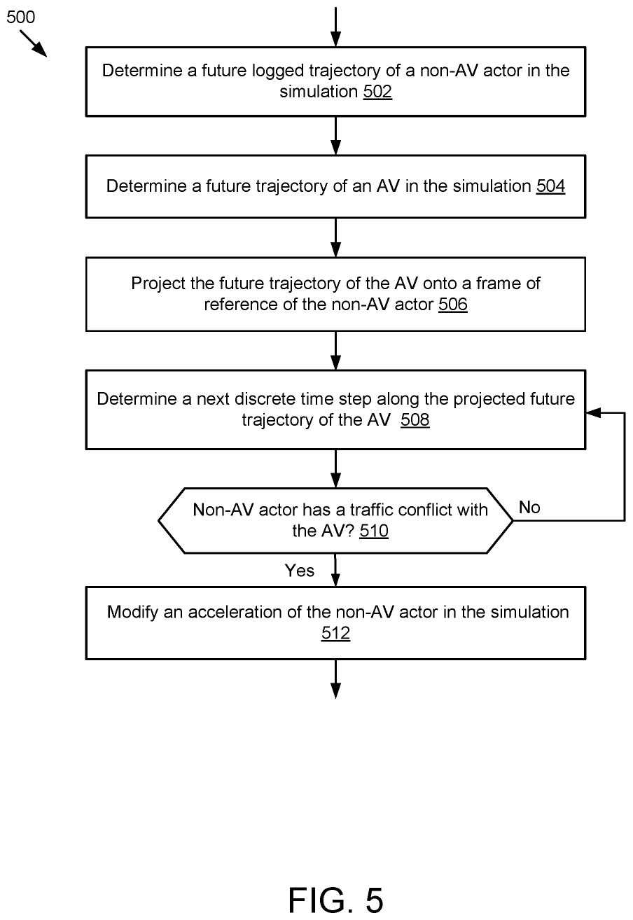

Referring now to FIG. 5, a method 500 of modifying a behavior of a non-AV actor in accordance with some implementations is illustrated. The method 500 may be a sequence of operations or process steps performed by a system of one or more computers in one or more locations, including, for example, the intelligent SFL system 160 in the computing system 172 of FIG. 2, by another computer system that is separate from the intelligent SFL system 160 in FIG. 2, or any combination thereof. Moreover, while in some implementations, the sequence of operations may be fully automated, in other implementations some steps may be performed and/or guided through human intervention. Furthermore, it will be appreciated that the order of operations in the sequence may be varied, and that some operations may be performed in parallel and/or iteratively in some implementations.

In block 502, the system determines a future logged trajectory of a non-AV actor in a simulation. For example, the system executes the simulation based on an intelligent simulation scenario. The system queries the original log file for a future logged trajectory of the non-AV actor in the simulation.

In block 504, the system determines a future trajectory of an AV in the simulation. For example, the system determines the future trajectory planned by the AV by querying the AV for its predicted state in the simulation.

In block 506, the system projects the future trajectory of the AV onto a frame of reference of the non-AV actor. For example, the frame of reference of the non-AV actor is orthogonal curvilinear coordinates (OCC) frame. In the simulation, the non-AV actor perceives the world in the OCC frame defined by its route, rather than in Cartesian coordinates. The non-AV actor perceives other actors' positions in the simulation in terms of their longitudinal, lateral, and loft displacements along its own route.

In block 508, the system determines a next discrete time step along the projected future trajectory of the AV.

In block 510, the system determines whether the non-AV actor has a traffic conflict with the AV. In some implementations, the system determines whether the non-AV actor is going to have a traffic conflict with the AV at a future point in time and space in the simulation. For example, the traffic conflict may include an upcoming collision, a merge navigation, an intersection navigation, following in a same lane, etc.

If in block 510, the system determines that the non-AV actor has no traffic conflict with the AV, then the system loops back to block 508. The system continues to iteratively step forward along the projected future trajectory of the AV at a discrete time step in the simulation.

On the other hand, if in block 510, the system determines that the non-AV actor has a traffic conflict with the AV, then the system proceeds to block 512.

In block 512, the system modifies an acceleration of the non-AV actor in the simulation. For example, the system uses an actor behavioral model to modify the acceleration of the non-AV actor along the longitudinal component of its OCC frame in the simulation. In some implementations, the system may have access to different behavioral models associated with the non-AV actor that can initiate different intelligent behaviors in the simulation. The system may choose a minimum longitudinal acceleration for the non-AV actor from among the different intelligent behaviors. For example, the system chooses the minimum acceleration as a heuristic for the safest among the different intelligent behaviors.

The previous description is provided to enable practice of the various aspects described herein. Various modifications to these aspects will be understood, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout the previous description that are known or later come to be known are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is understood that the specific order or hierarchy of blocks in the processes disclosed is an example of illustrative approaches. Based upon design preferences, it is understood that the specific order or hierarchy of blocks in the processes may be rearranged while remaining within the scope of the previous description. The accompanying method claims present elements of the various blocks in a sample order, and are not meant to be limited to the specific order or hierarchy presented.

The previous description of the disclosed implementations is provided to enable others to make or use the disclosed subject matter. Various modifications to these implementations will be readily apparent, and the generic principles defined herein may be applied to other implementations without departing from the spirit or scope of the previous description. Thus, the previous description is not intended to be limited to the implementations shown herein but is to be accorded the widest scope consistent with the principles and novel features disclosed herein.

The various examples illustrated and described are provided merely as examples to illustrate various features of the claims. However, features shown and described with respect to any given example are not necessarily limited to the associated example and may be used or combined with other examples that are shown and described. Further, the claims are not intended to be limited by any one example.

The foregoing method descriptions and the process flow diagrams are provided merely as illustrative examples and are not intended to require or imply that the blocks of various examples must be performed in the order presented. As will be appreciated, the order of blocks in the foregoing examples may be performed in any order. Words such as “thereafter,” “then,” “next,” etc. are not intended to limit the order of the blocks; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm blocks described in connection with the examples disclosed herein may be implemented as electronic hardware, computer software, or combinations of both. To clearly illustrate this interchangeability of hardware and software, various illustrative components, blocks, modules, circuits, and blocks have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the examples disclosed herein may be implemented or performed with a general purpose processor, a DSP, an ASIC, an FPGA or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some blocks or methods may be performed by circuitry that is specific to a given function.

In some examples, the functions described may be implemented in hardware, software, firmware, or any combination thereof. If implemented in software, the functions may be stored as one or more instructions or code on a non-transitory computer-readable storage medium or non-transitory processor-readable storage medium. The blocks of a method or algorithm disclosed herein may be implemented in a processor-executable software module which may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed examples is provided to enable others to make or use the present disclosure. Various modifications to these examples will be readily apparent, and the generic principles defined herein may be applied to some examples without departing from the spirit or scope of the disclosure. Thus, the present disclosure is not intended to be limited to the examples shown herein but is to be accorded the widest scope consistent with the following claims and the principles and novel features disclosed herein.

What is claimed is:

1. A method for evaluating the performance of an autonomous vehicle (AV), the method comprising:
determining a simulation scenario from log data, the simulation scenario including a first non-AV actor enabled to selectively deviate from its logged trajectory in the log data during simulation;
executing a simulation based on the simulation scenario;
monitoring the execution of the simulation;
based on the monitoring, determining whether a behavior-switching condition for the first non-AV actor in association with a traffic interaction including the AV is satisfied during the simulation;
responsive to determining that the behavior-switching condition for the first non-AV actor in association with the traffic interaction including the AV is satisfied during the simulation, modifying, using a first behavioral model, a behavior of the first non-AV actor to deviate from its logged trajectory; and
determining a performance metric based on the simulation.

2. The method of claim 1, further comprising:
responsive to modifying the behavior of the first non-AV actor to deviate from its logged trajectory, determining whether a behavior-switching condition for a second non-AV actor in association with the first non-AV actor is satisfied during the simulation, the second non-AV actor included in the simulation scenario and enabled to selectively deviate from its logged trajectory in the log data during the simulation; and
responsive to determining that the behavior-switching condition for the second non-AV actor in association with the first non-AV actor is satisfied during the simulation, modifying, using a second behavior model, a behavior of the second non-AV actor to deviate from its logged trajectory.

3. The method of claim 1, wherein determining whether the behavior-switching condition for the first non-AV actor in association with the traffic interaction including the AV is satisfied during the simulation comprises:
determining a future logged trajectory of the first non-AV actor in the simulation;
determining a future trajectory of the AV in the simulation; and
determining whether the first non-AV actor has a traffic conflict with the AV at a future point in time and space in the simulation using the future logged trajectory of the first non-AV actor and the future trajectory of the AV,
wherein the traffic conflict defines the behavior-switching condition.

4. The method of claim 3, wherein determining whether the first non-AV actor has the traffic conflict with the AV at the future point in time and space in the simulation using the future logged trajectory of the first non-AV actor and the future trajectory of the AV comprises:
projecting the future trajectory of the AV onto a frame of reference of the first non-AV actor; and
determining, at each of a plurality of discrete time steps along the projected future trajectory of the AV, whether the first non-AV actor has the traffic conflict with the AV.

5. The method of claim 1, wherein modifying the behavior of the first non-AV actor to deviate from its logged trajectory comprises modifying an acceleration of the first non-AV actor.

6. The method of claim 5, wherein modifying the acceleration of the first non-AV actor comprises:
determining the acceleration of the first non-AV actor that maintains an acceptable following distance behind the AV in a same lane as the AV.

7. The method of claim 5, wherein modifying the acceleration of the first non-AV actor comprises:
determining the acceleration of the first non-AV actor that prevents a collision with the AV.

8. The method of claim 5, wherein modifying the acceleration of the first non-AV actor comprises:
determining whether the first non-AV actor has to yield to the AV in a traffic conflict, the traffic conflict being a merge; and
responsive to determining that the first non-AV actor has to yield to the AV in the traffic conflict, determining the acceleration of the first non-AV actor to yield to the AV.

9. The method of claim 5, wherein modifying the acceleration of the first non-AV actor comprises:
determining whether the first non-AV actor has a right of way in a traffic conflict with the AV, the traffic conflict being an intersection; and
responsive to determining that the first non-AV actor has no right of way in the traffic conflict with the AV, determining the acceleration of the first non-AV actor to stop at the intersection.

10. The method of claim 1, wherein the behavior switching condition evaluates at least one from a group of:
a deviation of the AV from its logged trajectory in the log data during the traffic interaction with the first non-AV actor,
a divergence threshold between a planned trajectory of the AV and its logged trajectory in the log data,
a current distance threshold between the AV and the first non-AV actor,
a change in a state of dynamic elements other than non-AV actors,
a presence of static elements, and
a proximity to traffic infrastructure.

11. The method of claim 1, wherein determining the performance metric based on the simulation further comprises:
determining an evaluation set of simulation scenarios, each simulation scenario in the evaluation set including one or more non-AV actors enabled to selectively deviate from their logged trajectory;
executing the simulation for each simulation scenario in the evaluation set; and
determining a precision and recall of the performance metric based on the simulation.

12. The method of claim 1, wherein the performance metric measures instances of a suboptimal outcome in the performance of the AV.

13. The method of claim 2, wherein the first and the second behavior models are machine learning models, each trained from a plurality of logged trajectories of actors in real-world driving data.

14. The method of claim 2, wherein parameters of the first and the second behavior models are optimized using a nonlinear least squares optimization method to follow logged trajectories.

15. A system comprising one or more processors and memory operably coupled with the one or more processors, wherein the memory stores instructions that, in response to the execution of the instructions by one or more processors, cause the one or more processors to perform operations including:
determining a simulation scenario from log data, the simulation scenario including a first non-AV actor enabled to selectively deviate from its logged trajectory in the log data during simulation;
executing the simulation based on the simulation scenario;
monitoring the execution of the simulation;
based on the monitoring, determining whether a behavior-switching condition for the first non-AV actor in association with a traffic interaction including an AV is satisfied during the simulation;
responsive to determining that the behavior-switching condition for the first non-AV actor in association with the traffic interaction including the AV is satisfied during the simulation, modifying, using a first behavioral model, a behavior of the first non-AV actor to deviate from its logged trajectory; and
determining a performance metric based on the simulation.

16. The system of claim 15, wherein the operations further comprise:
responsive to modifying the behavior of the first non-AV actor to deviate from its logged trajectory, determining whether a behavior-switching condition for a second non-AV actor in association with the first non-AV actor is satisfied during the simulation, the second non-AV actor included in the simulation scenario and enabled to selectively deviate from its logged trajectory in the log data during the simulation; and
responsive to determining that the behavior-switching condition for the second non-AV actor in association with the first non-AV actor is satisfied during the simulation, modifying, using a second behavior model, a behavior of the second non-AV actor to deviate from its logged trajectory.

17. The system of claim 15, wherein determining whether the behavior-switching condition for the first non-AV actor in association with the traffic interaction including the AV is satisfied during the simulation comprises:
determining a future logged trajectory of the first non-AV actor in the simulation;
determining a future trajectory of the AV in the simulation; and
determining whether the first non-AV actor has a traffic conflict with the AV at a future point in time and space in the simulation using the future logged trajectory of the first non-AV actor and the future trajectory of the AV,
wherein the traffic conflict defines the behavior-switching condition.

18. The system of claim 17, wherein determining whether the first non-AV actor has the traffic conflict with the AV at the future point in time and space in the simulation using the future logged trajectory of the first non-AV actor and the future trajectory of the AV comprises:
projecting the future trajectory of the AV onto a frame of reference of the first non-AV actor; and
determining, at each of a plurality of discrete time steps along the projected future trajectory of the AV, whether the first non-AV actor has the traffic conflict with the AV.

19. The system of claim 15, wherein modifying the behavior of the first non-AV actor to deviate from its logged trajectory comprises modifying an acceleration of the first non-AV actor.

20. The system of claim 15, wherein determining the performance metric based on the simulation further comprises:
determining an evaluation set of simulation scenarios, each simulation scenario in the evaluation set including one or more non-AV actors enabled to selectively deviate from their logged trajectory;
executing the simulation for each simulation scenario in the evaluation set; and
determining a precision and recall of the performance metric based on the simulation.
